(19) United States
(12) Patent Application Publication
(10) Pub. No.: US 2026/0037691 A1
(43) Pub. Date: Feb. 5, 2026

(54) STRUCTURE DETECTION FOR OPTIMIZING THE USE OF RESOURCES IN PHYSICAL SYSTEMS

(71) Applicant: SYTE GMBH, Münster (DE)

(72) Inventors: David NELLESSEN, Münster (DE); Matthias ZÜHLKE, Münster (DE); Sven KÖNNING, Münster (DE)

(21) Appl. No.: 18/698,728

(22) PCT Filed: Oct. 1, 2022
(86) PCT No.: PCT/EP2022/077421

§ 371 Date: Jul. 21, 2025

(30) Foreign Application Priority Data
Oct. 4, 2021 (LU) 102861

(51) Int. Cl. G06F 30/27

(52) U.S. Cl. CPC G06F 30/27

(57) ABSTRACT

The present invention relates to a method for optimizing the use of volume and/or surface area in a generic physical system (for example development plans, logistics and storage systems, quantum computers, solid-state systems, electron gases, plasmas), comprising the following steps: identifying a physical system in an n-dimensional space, in particular three-dimensional space, identifying an (n−1)-dimensional space, in particular two-dimensional space, which is suitable for describing an (n−1)-dimensional projection of the physical system in the n-dimensional space, providing n-dimensional point data, in particular lidar data, and/or LoD data, providing secondary data comprising (n−1)-dimensional data, in particular polygon data, in particular a cadastre, identifying one or more subsystems in the physical system, in particular using the secondary data, in particular also by assigning secondary data to the subsystems, determining subsystem data of at least two subsystems that describe variables of the respective subsystem, in particular comprising the secondary data of the respective subsystem and the n-dimensional point data and/or LoD data in relation to the respective subsystem, in full or in part, selecting at least one subsystem, using a supervised-learning machine-learning model, in particular a trained artificial neural network and/or a linear regression, to predict properties of the selected subsystem on the basis of the secondary data of the selected subsystem and of the subsystem data of other, non-selected subsystems. The invention additionally relates to corresponding computers, computer programs, computer networks, data and computer-readable data media and relevant uses.

### FIELD OF THE INVENTION

The present invention generally relates to the field of physical systems and their optimization and optimal use. Many physical systems can be described by descriptions which exist, for example, in a two-, three- or even higher-dimensional space.

It is often desirable for the progress and improvement of physical systems to recognize potential improvements to the systems with confidence, to assess their admissibility and to implement the proposed improvements in reality.

In one embodiment, the development or use of space in a physical system can be optimized, resulting in improved use of space and volume in the system.

### TECHNICAL BACKGROUND

Specifications for the physical systems, e.g. laws such as laws of nature, but also artificial or man-made laws (e.g. statutory provisions of building planning law), can possibly restrict the possible or permissible modifications for the physical systems. Another example is given by quality assurance regulations, which define quality and/or homogeneity requirements for an electronic or mechanical component, for example.

Various techniques known from the state of the art are briefly outlined below.

In particular, cadastral data is known from the state of the art. Such data, which is often fragmented and specialized for certain geographical regions, can be retrieved via electronic systems. One example of this is an official real estate cadastre information system (ALKIS).

Such data is usually measured by surveying technicians or publicly appointed surveyors who carry out geodetic measurements on site using appropriate mobile measuring equipment, which can be transported to the location to be surveyed, set up there and used successively.

The data is also generally limited to very simplified measurement parameters, particularly with regard to the complex structure actually present, and therefore only provides extremely rough insights into the actual conditions. Substructures such as individual details of individual buildings are often ignored. In the most common cases, surveyors or publicly appointed surveyors only measure building perimeters, usually only in the form of two-dimensional data. Sometimes a number of full storeys of a building is also given, as read off from the building structure by the surveying technician or publicly appointed surveyor.

A procedure is also known from the state of the art which basically provides a measurement of the earth's surface together with the objects located on it. An example of this technology is Light Detection and Ranging (LIDAR or LiDAR). For example, a LIDAR measurement can be carried out as grid-based laser scanning on board an aircraft by measuring the structures under the aircraft. However, this data often does not go beyond data in the form of spatial point data (“point clouds”). One of the reasons for this is that LIDAR is essentially based on distance measurements. In particular, LIDAR as such only creates point clouds without interpretation, which makes it difficult to analyze LIDAR data in a way that provides further profit and insight.

In addition, point clouds are often affected by individual measurement errors (e.g. “outliers”), which can lead to incorrect conclusions even if the point cloud data is studied in detail. This leads to massive subsequent errors, especially in automated data processing.

Another technology from a different technical field is provided by artificial neural networks (ANN). For example, it is known that the translation service provider DeepL uses such networks to convert texts from one natural language into another natural language with a high degree of information accuracy. This is possible thanks to extensive databases, such as the Linguee database, which enable the ANN(s) to be trained accordingly. The ANN(s) are precise, but only for the stated purpose.

The state of the art has the disadvantage that enormous data potential remains unused. The fragmentation of data and data sources and different formats make it even more difficult to gain insight into potential opportunities for change and improvement.

There are similar problems in other physical systems such as solid-state physics (e.g. two-dimensional electron gases) and quantum computers.

The present invention is therefore based on the technical task of providing methods that overcome the disadvantages of the prior art and enable new solutions. In particular, a method for optimizing and identifying potential improvements in physical systems, especially physical systems that are as generic as possible, is to be created. Exemplary applications of the inventions are conceivable in the real estate sector, the logistics sector, control and regulation technology, integrated circuits and quantum computers.

The aim is to create more flexible, scalable, transferable, secure and reliable solutions. The factor of cost minimization also plays an important role. The methods should be able to operate on technical system data, in particular measured “raw data”. Furthermore, the methods should not only be able to suggest potential optimizations of physical systems, e.g. as a simulation, but also implement these optimizations in reality by modifying the physical systems accordingly. The generic cross-field applicability, in particular for different physical systems of different nature, should be guaranteed.

The disadvantages of the prior art are overcome by the method according to claim 1, the computer, the computer program, the computer network, the data and the computer-readable data carrier according to claim 22 and the corresponding use according to claim 23.

### DESCRIPTION OF THE INVENTION

The present invention provides a method having the features of claim 1.

Further advantageous embodiments are given in the subclaims.

Accordingly, a method for optimizing volume and/or area utilization in a physical system is provided, comprising the following steps: identifying a physical system in an n-dimensional space, in particular three-dimensional space, identifying an (n−1)-dimensional space, in particular two-dimensional space, which is suitable for describing an (n−1)-dimensional projection of the physical system in n-dimensional space, providing n-dimensional point data, in particular LIDAR data, and/or 3D models in different levels of detail (LoD data), which in particular describe one or more surfaces, providing secondary data comprising (n−1)-dimensional data, in particular polygon data, in particular of a cadastre, which in particular describe one or more planes, identifying one or more subsystems in the physical system, in particular by means of the secondary data, in particular also by assigning secondary data to the subsystems, determining subsystem data of at least two subsystems which describe variables of the respective subsystem, in particular comprising the secondary data of the respective subsystem and the n-dimensional point data and/or LoD data for the respective subsystem, in whole or in part, selecting at least one subsystem, utilizing a machine learning model of supervised learning, in particular a trained artificial neural network and/or linear regression, for predicting properties of the selected subsystem based on the secondary data of the selected subsystem and the subsystem data of other, non-selected subsystems.

The method can be used for generic physical systems.

Physical systems are generic physical systems for whose structure and properties measurement data, i.e. technical data, can be provided.

Aspects of the invention are partly explained in the context of an exemplary embodiment for an application in proactive sustainable urban planning, but are not limited to this.

Thus, a step of identifying a physical system takes place in an n-dimensional space. In particular, this can be a three-dimensional space. It can also be a part/section of an n-dimensional space. n is a natural number. In a two-dimensional example with n=2, for example, a two-dimensional electron gas is described. It can be described classically or quantum mechanically, for example. In another example, it is a part/section of a three-dimensional space. In a further example, this space comprises built-up areas or plots of land. Buildings, including their roofs, can be located in this space. Various sizes or scales for systems are conceivable. For example, it could be neighborhoods, villages, cities, countries, continents or even a world map. Other limited structures are also conceivable, such as grid squares or the sum of different properties that are subject to uniform development laws or development plans.

Other physical systems are also conceivable. It should be emphasized that these physical systems are by no means limited to descriptions in n=3 dimensions. In a three-dimensional example, for example, various boxes or other structures for receiving and storing goods can be accommodated in large warehouses or the like. This example is also usually three-dimensional. There are also optimization requirements in this area where the present invention can be used. For example, isolated, very heavy boxes (boxes with a high weight due to their contents) should not be placed high up on top of other, very light boxes. Light boxes often have a light and also not very dimensionally stable content, and are therefore more at risk than heavy boxes of being damaged or “crushed” or in any case “pressed in” by other heavy boxes.

The invention can be used in a wide variety of fields. The use of the present invention is particularly profitable in such fields, where certain difficult to grasp and therefore not directly and precisely detectable requirements are placed on individual elements, in particular homogeneity requirements of the elements in relation to the areas surrounding them. Such applications include systems engineering applications, integrated circuits as well as data storage and quantum computing.

There is a step of identifying an (n−1)-dimensional space, in particular a two-dimensional space, which is suitable for describing an (n−1)-dimensional projection of the physical system in n-dimensional space.

For example, this is a two-dimensional surface such as a piece of ground, as can be shown on a simple map. In this example, buildings can be projected onto the two-dimensional map. As a rule, buildings here have a two-dimensional outline. With this projection, information is often lost, in particular about the height of the building, the shape of the roof, etc.

In one example, we are dealing with a two-dimensional projection of a building, a property, a neighborhood, a village, a city or a country. Several of these can also be contained in the two-dimensional area. In one example, this is the city of Munster, including the surrounding districts, or it is the federal state of NRW, Germany or Europe. However, it can also be just a small development area or the area of a construction project.

Corresponding data can be obtained for both the n- and the (n−1)-dimensional space, e.g. also retrieved from one or more databases. In particular, this data can also be measured within the scope of the invention. Combining different data sources and data is also possible. For example, self-measured data can be combined with data available in databases in a profitable and error-reducing manner.

In one example, n-dimensional point data can be used.

Three-dimensional point data is therefore ideal for a three-dimensional space with different properties and buildings. LIDAR data (Light Detection and Ranging) is particularly suitable. Alternatively or in combination, a LIDAR measurement can also be used in the context of the invention.

In Germany, for example, LIDAR point data that has already been measured can be obtained or retrieved from the state authorities. An exemplary suitable format for such data is LAS, but other formats for point clouds can also be used. In one example, the data is compressed, e.g. LAZ, which saves technical resources, especially during transmission and/or direct retrieval. This also saves time and results can be made available more quickly. Some point data can be or can be assigned to specific subsystems of a physical system. Such an assignment is based on technical considerations and/or knowledge of the technical structure and substructure of the physical system. Different variants and further developments will be explained in more detail later on.

In an alternative according to the invention, so-called LoD data is used. Level of Detail (LoD) describes 3D models in which data is available in different levels of detail. This has the advantage that the level of detail for a calculation can be freely selected and remains variable. This means that a suitable LoD level can be selected for each case, enabling adequate calculations and representations.

In simple terms, these are easy-to-use “block models” that can adequately describe buildings, for example. The data is reduced to the essentials and is also available in varying degrees of detail. These models are often generated from LiDAR data and therefore generally have a lower degree of accuracy than the LiDAR data itself.

LoD model-based data is particularly easy to handle and leads to short calculation times for queries, as these are less computationally intensive due to the LoD models.

As a further variant, LoD data can be derived, i.e. generated, from the LIDAR data within the scope of the invention. This results in a further intermediate step. In the following, calculations can then be made on the basis of the original LIDAR data and/or the LoD data derived therefrom.

Secondary data comprising (n−1)-dimensional data, in particular polygon data, in particular from a cadastre, is provided. This is therefore two-dimensional data, for example from a cadastre. Such data can, for example, be obtained from an official real estate cadastre information system (ALKIS). For example, the shape and location of properties and/or parcels can be taken from ALKIS data. Often only data on parcels is available, but the data on the plots can sometimes be reconstructed by cleverly recombining the parcels. Alternatively, this recombination can be carried out using information provided by the user. In the context of the present application, land parcels and parcels of land are essentially regarded as synonyms, unless the difference is explicitly emphasized. In many cases, a plot of land also corresponds to a parcel of land, i.e. the plot of land comprises only one parcel of land, whereby the ALKIS data provides information on the latter in any case. The outlines of buildings, for example, can also be taken from the ALKIS data. Furthermore, additional data or metadata (often e.g. information on the number of full storeys or the use or type of use) can be included.

In principle, statements on other sealed surfaces can also be contained in such a data set and then extracted from this data set. However, this is not usually the case, but this can be remedied by various further embodiments of the present invention. This will be discussed at the appropriate point. For example, terraces and parking spaces should be mentioned here.

In the case of a two-dimensional electron gas, the secondary data can comprise scalars.

In one example, the data or part of it is based on a standards-based exchange interface for the exchange of geoinformation (NAS). An exemplary format is the GML format (Geography Markup Language). The use of such a standardized format increases interoperability with existing systems and solutions.

In the case of a system that lives in four dimensions (e.g. Minkowski spacetime), the secondary data comprises three-dimensional data. For example, this secondary data corresponds to the spatial part of an observer's spatiotemporal reference system.

One or more subsystems are identified in the physical system, in particular using the secondary data. In one embodiment, for example, the system can be broken down into plots of land with the aid of ALKIS data. The secondary data corresponding to a plot of land and building can thus also be assigned to the subsystem.

Subsystem data can then be generated for subsystems. Such subsystem data is assigned to the subsystems and can describe variables of the respective subsystem. Such subsystem data can include the secondary data already mentioned. However, such subsystem data may also include the corresponding n-dimensional point or LIDAR data, for example over the subsystem property (e.g. obtained by corresponding “blending” of the data), or parts of this LIDAR data. The subsystem data can also contain other derived variables from other subsystem data. One example is a ground reference point. Another example could be a ridge height and/or an eaves height. The subsystem data can thus be extended as desired within the scope of the invention by further calculated or derived variables for the subsystem. The subsystem data can be used to train and utilize an artificial neural network. This will be explained in more detail later.

The secondary data can also be blended with the point data, e.g. the LIDAR point data. What is meant by this is explained below. For example, cadastral data describes two-dimensional polygons for parcels, plots and/or buildings on the land (e.g. in the form of the outline of the area covered by the building). In order to determine certain sizes of the house as accurately as possible from the LIDAR data, for example, LIDAR points can be selected which, when projected into the two-dimensional plane, lie above the property (“slicing” of the data). This increases the accuracy of the derivative measured variables, as sources of error can be cut off and thus avoided. For example, a tree near the house is not taken into account when determining the ridge and eaves height of the roof.

In another example, this increases the accuracy in legal terms. In many areas, the eaves height of a roof can be defined under building law in such a way that it must be measured exactly at the edge of the developed property, even if the roof overhangs. As trimming cuts off a roof that protrudes beyond the edge of the developed property, the accuracy of determining the size that is classified as particularly relevant under building law is increased. The relevant, trimmed points can be specially marked in the data so that a new determination is not necessary. This technique is suitable for all “blending processes” within the scope of the present invention and its further developments. This saves computing time, as the relevant data points are immediately available for further calculations thanks to the flags attached to them.

Important properties, measured variables and derivative properties as well as dimensions of use under building law will be discussed in detail later. At this point, we will only refer to the ridge and eaves height in relation to the roof of a building as an example. The combined use of cadastral and LIDAR data makes it possible to determine the exact height of any building. Cadastral and LIDAR data is available with good area coverage and accuracy, partly commercially and partly even free of charge.

The example described above works particularly well if the building outlines, for example from the ALKIS data, are known very precisely. The method is therefore the preferred method of choice for Germany, for example, where the building outlines have been measured very precisely as part of the ALKIS data.

Reference should also be made at this point to other alternative procedures within the scope of the present invention. The point data can therefore, but need not necessarily, be intersected with the building outline, for example. All point data over the entire property can also be taken into account, in each case adequately. Point data from neighboring properties can even be included.

In another example, a specially trained machine learning model is used to determine the buildings, building outlines and/or derivative variables such as the ridge and/or eaves height etc. as precisely as possible from the point data. This approach is particularly precise and also covers “outlier cases” such as special features of non-conventional buildings with ease. For example, an artificial neural network is used as a machine learning model.

In one example, the machine learning model is trained with data from Germany. In Germany, the building outline data from the ALKIS data is available with comparatively high precision. The trained machine learning model can then also be used excellently in regions abroad where the building outlines are not so precisely known or measured and are therefore not so precisely available in the context of cadastral data. This not only increases the overall precision, but the machine learning model can also be used to extend the precision to geographical regions where sufficiently precise data is not available.

LIDAR measurements specially adapted to the purpose of the present invention can also be carried out in a separate form within the scope of the present invention. Thus, special adaptations are possible, such as a higher grid/scan resolution in cities or densely populated areas.

Subsystem data should be generated for the numerous subsystems in a suitable example. For example, these are the above-mentioned important properties, measured variables and other derivative properties. The subsystem data should contain technically interesting and/or relevant data on the subsystems, for example from a construction law perspective. In another example of quality assurance for integrated circuits, this could be certain technical requirement data and parameters that a component that is to pass the quality assurance process must fulfill.

One subsystem is then selected. There could also be several, but for the sake of simplicity, the case of a single selected subsystem will be discussed below.

This subsystem is now to be examined for optimizability and/or buildability/improved usability. For this purpose, according to the invention, a specially trained machine learning model, in particular an artificial neural network (network), is used. This is done on the basis of the secondary data of the selected subsystem on the one hand and the subsystem data of other, in particular non-selected, subsystems on the other. This data can, for example, represent the input/the input variables that are applied to the corresponding input neurons of the artificial neural network. Deep neural networks are particularly suitable as artificial neural networks, but other techniques in the field of artificial intelligence and machine learning can also be used.

The secondary data of the selected subsystem includes, for example, the cadastral data on the land and/or parcel. Information on buildings may also be included. In one example, variables derived from this can also be included. For example, this may be a floor area. In one example, the secondary data mentioned here does not include any cadastral data on a building that may exist on a property. This is particularly useful for a potential analysis for the subsystem, as properties of land are difficult to change, but properties of buildings can be modified if potential for improvement is identified. For example, when predicting the properties of buildings that could potentially be erected on a plot of land, it is therefore advantageous to include the properties of the land, but not to falsify the analysis by including the “status quo”, i.e. the current use of the area by buildings, for example.

In one example, a site in an area is occupied by a vacant, dilapidated building (extreme example). However, this building can be demolished, i.e. removed from the site, if this is necessary or expedient for progress in order to make room for something new. If the machine learning model, in particular the artificial neural network, makes a suggestion or a prediction which, for example, has a high degree of utilization and possibly other advantageous parameters, it can be considered to make sense and improve the structure to implement the suggestion or prediction in reality.

The subsystem data of other subsystems, in particular non-selected subsystems, are relevant for the correct detection of specifications, in particular environmental specifications, by the artificial neural network. In particular, the artificial neural network uses this subsystem data as features/influencing factors to capture, for example, various explicit relevancies and requirements that are difficult to capture otherwise, such as homogeneities in particular. For example, there may be building law requirements for a “homogeneous image” or, in one example, the height of a new building must match the surrounding buildings—at least approximately.

In another example, various transistors are incorporated into an integrated circuit as subsystems. Certain parameters, such as voltages etc., can be subject to certain homogeneity requirements for ideally functioning circuits.

There are also quantum computers in advanced stages of development that comprise several qubits. In many examples, these qubits interact with each other through quantum entanglement as well as with external sources such as fields. It is therefore essential for an ideally functioning and maximally utilized quantum computer that the qubits, which here represent the subsystems or are incorporated in the subsystems, in particular neighboring qubits, directly adjacent or more distantly adjacent, are as homogeneous as possible. This technical effect can be achieved according to the invention by means of the subsystem data of the surrounding qubits when predicting a selected qubit.

Feature engineering and the associated definition of the—potentially—relevant features with which the artificial neural network works have a major influence on the quality of the results obtained. In the context of further developments of the present invention, corresponding aspects will be discussed in detail.

In many applications of the invention, secondary data comprises features that describe environmental and/or spatial factors that are difficult to change. These are often factors that are determined or fixed by external circumstances. Other factors may be included which can be regarded as highly homogeneous in a permissible approximation, e.g. a temperature, an air pressure or an air humidity. In many cases, it is also the case that the secondary data does not include any characteristics that are treated as variables in the analysis of improvement potentials. Excluding these characteristics has the advantage that they can be predicted more precisely and without the influence of disturbing factors by the artificial neural network.

In many applications of the invention, it is also the case that subsystem data includes features that are treated as variables in the analysis of improvement potentials. Taking these characteristics into account in the subsystem data has the advantage that they enable precise prediction of these or similar characteristics by the artificial neural network for the selected subsystem.

In particular, the invention combines secondary data of the selected subsystem or subsystems with subsystem data of subsystems. In particular, the invention combines secondary data of the selected subsystem or subsystems with subsystem data of other subsystems which are not selected. Through this deliberate choice for feature engineering, accurate and reliable results can be achieved, which recognize potential improvements for the system and enable their implementation.

The combination of the relevant system data thus opens up new, previously untapped potential for system improvement, while maintaining external requirements for systems, in particular local or semi-local homogeneity requirements.

The machine learning model itself provides a lossy compression of the input and training data.

According to a further development, the machine learning model or the artificial neural network is and/or was trained using a selected subset of existing subsystems, in particular by means of supervised learning of the artificial neural network.

In one example, this selection is made manually, for example by an employee or user. For example, corresponding subsystems, e.g. also in a certain region, are or were selected for this purpose, which already have certain high levels of structural use (and are therefore good examples of efficient use of space and volume). In the example, such conditions are desirable. Therefore, such desirable or advanced cases of subsystems should preferably be selected. By training the artificial neural network through supervised learning with these selected subsystems, the suggestions/predictions of the network also tend to be oriented towards high building utilization. This makes the suggestions particularly useful for improving the physical system, and the network converges more quickly on useful solutions. Unnecessary training of the network as well as “wrong” or useless training are avoided. This pre-selection gives the overall system an additional “offset” or “drive”, which converts the dynamics in the direction of continuous improvement. This avoids simply replacing subsystems with very similar subsystems without significant improvement.

According to a further development, subsystems are selected in particular which have a high utilization, in particular volume and area utilization, in the secondary and/or subsystem data, characterized in particular by exceeding and/or falling below threshold values in relation to the secondary and/or subsystem data.

Such threshold values are an easy and inexpensive variant to implement for the “drive” that causes the desired temporal-dynamic system development. They can be absolute threshold values or relative threshold values. A relative threshold value can, for example, be defined in relation to an average value such as an arithmetic mean or a median.

More complex systems such as decision trees can also be used to delimit and select the relevant subsystems.

According to a further development, the method further comprises a step of providing photogrammetry data relating to the n- and/or (n−1)-dimensional space and deriving at least one variable from the photogrammetry data, in particular in combination with the secondary data and/or subsystem data.

The addition of photogrammetry data makes it possible to determine the actual conditions of a subsystem even more precisely, especially on the basis of LIDAR point cloud data.

For various dimensions of building use, such as the ridge and eaves height of a roof, it may be necessary or useful to precisely determine a ground reference point for the subsystem (e.g. a “height above zero”). In a simple embodiment, for example, cadastral data showing a plot of land and one or more buildings located on it are blended with LIDAR data. For example, a ground reference point can then be determined by averaging the reference points not located in the area of the building. Alternatively, an existing pre-classification in the LIDAR data can also be used, e.g. based on all points with a “Ground” flag in the LIDAR data. However, it has been shown that a particularly precise determination can only be achieved by combining this with photogrammetry. Based on photogrammetry and the corresponding selection and processing of the LIDAR points, a higher precision is achieved than with other methods for determining the ground reference point.

The photogrammetry data can also be used to determine other reference points, reference values, derivative values and dimensions of structural use. For example, a size or an actual proportion of sealed areas in the total areas can be determined more precisely, or further structural statements about the nature, use, type of use, etc. of the subsystem or parts thereof are possible. Corresponding further classification of subsystems based on certain characteristics of subsystems is made possible. The use of photogrammetry data can also have an effect on the calculation of complex variables. In one example, it is possible to recognize whether an attic is developed or used or not.

The combination of data with photogrammetry data also proves to be very advantageous for other system types. In the case of microelectronics and nanoelectronics, for example, this results in further profitable insights into the structures present, especially in combinative, synergetic evaluation together with the other data already mentioned.

According to a further development, the method also comprises a step of recognizing at least one sealed surface and its dimensions on the basis of the photogrammetry data. By recognizing and successively taking into account already existing sealed areas, the result is further specified. In the case of building regulations and development plans, the proportion of sealed surfaces in the total area is often of great importance. In this way, legal requirements can be met. It should be noted that the legal requirements are not of a purely abstract legal nature, but serve to enable technical effects (including the avoidance of undesirable technical effects). The proportion of sealed surfaces is relevant for the overall system, for example in the case of high precipitation, which should run off (“seep”) into the ground without disturbing, destroying or negatively influencing the overall system. Flooding is a major problem for people and obviously disrupts the sustainability of structural development. According to further training, the potential of structural use can be further exploited without jeopardizing the physical system and its intended function and use. For example, an impermissible exceeding of critical limit values is avoided in advance.

According to a further development, the method further comprises a step of determining a ground reference point by recognizing an object in the photogrammetry data which is suitable for serving as a ground reference point, in particular manhole and manhole covers. There can also be several objects.

This means that the ground reference point is once again more precisely determined and closer to the actual conditions that exist in the physical system and are to be determined from the measurement data. A more precise determination of the ground reference point can also have a strong effect on derivative variables such as ridge height, eaves height and storey height. In addition, different definitions of ground reference points (e.g. because these different definitions are relevant and must be taken into account under building law) can be complied with. For example, if a ground reference point is defined as a manhole cover to the sewer system, this can be measured or determined from the measurement data. If, in another example, it is the height of a kerb or kerb edge, this definition of dimensions can also be met using the photogrammetry data.

According to a further development, the method also includes a step of intersecting the dimensions of the detected object with the n-dimensional point data to generate intersection point data. For example, only LIDAR point data in the corresponding area is used to determine a reference point, for example the points above or in the area of the manhole or manhole cover (a “gully”).

According to a further development, the method further comprises a step of forming an average of the intersection point data to determine the ground reference point. The formation of the average over a well-chosen set of data points again reduces the error and leads to the highly precise determination of the ground reference point as well as all derivative variables to be determined depending on this.

According to a further development, the method further comprises a step of intersecting n-dimensional point data with a building part of a subsystem defined by the secondary data to generate intersection point data and a step of marking the points of the intersection point data that fall within the area of the building part in the n-dimensional point data. In this way, all points that lie in the area or above the building, as defined in the cadastre, are marked. This technique has numerous advantages.

For example, in order to determine certain parameters of the house as accurately as possible from LIDAR data, LIDAR points can be selected which, when projected into the two-dimensional plane, lie above the property. This increases the accuracy of the derived measured variables, as sources of error can be cut off and thus avoided. For example, a tree near the house is not taken into account when determining the ridge and eaves height of the roof.

In another example, this increases the accuracy in legal terms. In many areas, the eaves height of a roof can be defined under building law in such a way that it must be measured exactly at the edge of the developed property, even if the roof overhangs. As trimming cuts off a roof that protrudes beyond the edge of the developed property, the accuracy of determining the size that is classified as particularly relevant under building law is increased. The relevant, intersected points can be specially marked in the data so that a new determination is not necessary. This saves computing time, as the relevant data points are immediately available for further calculations thanks to the flags attached to them.

Normal vectors and curvatures can be determined from the point data, especially the intersected point data. These are useful quantities for a large number of subsequent calculations, which is why it saves computing time and resources to have these quantities available. In addition, normal directions and angles, whether in discrete or continuous form, such as for a round roof, are architecturally relevant quantities.

The example described above works particularly well if the building outlines, for example from the ALKIS data, are known very precisely. The method is therefore the preferred method of choice for Germany, for example, where the building outlines have been measured very precisely as part of the ALKIS data.

At this point, further applications of the further development of the invention will be discussed. As already discussed above, in a further example, a special machine learning model specially trained for this purpose can also be used to determine the buildings, building outlines and/or derivative variables such as the ridge and/or eaves height etc. as precisely as possible from the point data. This approach is particularly precise and also covers “outlier cases” such as special features of non-conventional buildings with ease. For example, an artificial neural network is used as a machine learning model.

In one example, the machine learning model is trained with data from Germany. In Germany, the building outline data from the ALKIS data is available with comparatively high precision. The trained machine learning model can then also be used excellently in regions abroad where the building outlines are not so precisely known or measured and are therefore not so precisely available in the context of cadastral data. This not only increases the overall precision of, but the machine learning model can also be used to confidently extend the precision to geographical regions where sufficiently precise data is not available.

The further training described above thus creates valuable training data that enables the training of the machine learning model mentioned above and thus enables the technical effects mentioned above to be achieved.

According to a further development, points are also classified and marked as roof points on the set of intersection point data, in particular by clustering and/or by unsupervised learning, in particular on the basis of the Euclidean distance between the points as a relevant measure and/or on the basis of the vertical distance, in particular the vertical or z-component, between the points as a relevant measure.

This procedure reduces the influence of parts of the point cloud that do not belong to the actual roof. For example, a chimney or the crown of a tree protruding above the roof can be “clustered away” and thus rendered harmless for the determination of the roof. In one example, dormers are also “clustered away”; in another example, such dormers are deliberately retained as part of the roof.

For example, the Euclidean distance (or its square or another equivalent value that depends on the Euclidean distance) between two points in the point cloud is used as a measure for clustering. This is a spatially isotropic measure and therefore has the advantage that the results are invariant to rotation. Normal vectors are also well suited for clustering.

It has been shown that with regard to a sovereign separation of the roof from components of the point cloud that do not belong to the roof in the narrower sense, a particularly suitable measure to be taken into account is the vertical distance. In other words, clustering is performed according to the z-component or in the vertical direction or according to the distance from the ground (or an equivalent value). The results obtained in this way are particularly successful and precise. Due to this surprising technical effect, clustering by z-component represents a preferred further development of the invention.

Clustering by normal vector, Euclidean distance and vertical distance is again more precise if these variables are used simultaneously in a clustering procedure, for example. However, they can also complement each other by using several downstream clustering methods, for example first by Euclidean distance (possibly taking into account the normal vectors) and then by vertical distance (possibly also taking into account the normal vectors). This makes the results particularly precise, as smaller structures (e.g. a chimney, roof shafts, air conditioning systems, satellite dishes, etc.) can still remain in the data set recognized as a roof after the first clustering process, but can then be removed with confidence in a successive post-clustering (e.g. by z-component).

The roof identified in this way allows precise dimensions to be determined in relation to the roof, the building and its use.

For example, a volume of the building can be calculated. Technically, this is done in a particularly advantageous way by numerically integrating the z-components of the point cloud over the relevant surface. This result is particularly precise and at the same time avoids having to make unnecessary model assumptions, e.g. about the shape of a roof. In addition, this method benefits from a ground reference point that has previously been determined particularly precisely and correctly. This synergetic effect significantly reduces errors and error propagation and the determination of variables, such as the volume, is even more precise.

Another variable that can be calculated precisely in this way is the floor area. This is also helpful for the correct calculation of a floor area index (GFZ). A particularly advantageous numerical method for calculating the floorspace is numerical integration over the built-up area by dividing by a storey height. For example, a storey height can be known or it can be estimated, particularly depending on the type of use (e.g. residential or commercial).

The result achieved by numerical integration is particularly precise and at the same time avoids having to make unnecessary model assumptions, e.g. about the shape of a roof. This method also benefits from a ground reference point that has been determined precisely and correctly beforehand.

It is also possible to determine usable storeys. A method in which cross-sections are formed through the building or its point cloud has proven to be particularly suitable. The distances between the cross-sections are determined, for example, by a storey height. For example, a storey height can be known or it can be estimated, particularly depending on the type of use (e.g. residential or commercial). Cross-sections with a cross-sectional area above a certain threshold value (minimum area of a storey) then count as a storey when determining the number of usable storeys. For example, such a threshold can only be set at five square meters. This helps to avoid incorrect estimates in border areas (just on the threshold to the next storey). It also helps to avoid errors caused by superstructures such as chimneys, unless these have already been successfully removed from the roof or the roof point cloud, i.e. “clustered away”. Also, such attic spaces can only be used in an economically significant way above a certain size (e.g. if they are suitable for renting out as rooms or apartments).

The “roof detection” discussed here can also take normal vectors and curvatures into account. This makes the result even more precise. For example, roofs are generally only rarely “curved”.

According to a further development, the method further comprises a step of classifying and marking points as roof points on the basis of a trained second machine learning model, in particular a second artificial neural network.

It has been shown that the use of a machine learning model can also be superior to other strategies for carrying out this step. This increases precision once again.

As explained elsewhere, this can be particularly useful if, for example, the outlines of buildings in a geographical region of interest have not been accurately surveyed and are therefore not precisely known.

According to a further development in this context, the second machine learning model is and/or was trained by a method comprising a step of intersecting n-dimensional point data with a building part of a subsystem defined by secondary data to generate intersection point data.

This increases precision. For example, data in a geographical region where building outlines have been precisely measured (e.g. Germany) can also be used with the blending technique to generate the intersection point data. With this data, the (second) machine learning model can then be trained in such a way that it can also independently perform the classification according to the invention in other regions without having to rely on data of precise building outlines, which are not available accurately in many relevant geographical regions, in particular.

According to a further development, points are also classified and marked as roof points on the set of intersection point data, in particular by clustering and/or by unsupervised learning, in particular on the basis of the Euclidean distance between the points as a relevant measure and/or on the basis of the vertical distance, in particular the vertical or z-component, of the points from one another as a relevant measure and/or on the basis of normal vectors.

For the advantages of these other features, please refer to the discussion above. The use of this technique in relation to the generation of good training data to train the second machine learning model has also been proven in practice and has proven to be extremely advantageous. The better and more correct determination of roofs in the context of this clustering technique, the advantages of which have already been described above, can thus also successively benefit the quality of the training data, the quality of the training of the second machine learning model and finally the classification results for roof points under the intended use of the second machine learning model.

Curvatures can also be taken into account in the “roof detection” discussed here. This makes the result even more precise. For example, roofs are generally only rarely “curved”.

According to a further development, an incoming feature vector of the artificial neural network comprises property-related secondary data of the selected subsystem on the one hand and subsystem data of other, non-selected subsystems on the other. In particular, subsystems in the immediate vicinity are regularly relevant here.

For example, but not exclusively, such property-related secondary data includes the area, location, shape, dimensions or use (e.g. according to the land use plan) of a property.

For example, but not exclusively, such subsystem data from other, non-selected subsystems includes data such as floor area ratio, floor area ratio, ridge height, eaves height, volume, number of usable storeys, roof angle, area, location, shape or dimensions of a property, number of full storeys, type of use (e.g. according to the land use plan) and much more.

All quantities mentioned in this patent document in relation to land and/or buildings can potentially be included in the subsystem data.

This allows the artificial neural network to be trained with appropriate data to make suitable predictions or suggestions.

To put it simply, the building on the property under consideration (see selected subsystem) is simply not included in the calculation, then the artificial neural network can be used to make a suggestion or prediction. It takes into account all relevant “environmental factors”. On the one hand, these are properties of the property (see secondary data of the selected subsystem). On the other hand, these are the properties including buildings and their properties in the surrounding area, in particular the immediate vicinity (subsystem data of the other subsystems). This structuring in relation to input and output variables allows a particularly efficient and targeted use of the artificial neural network and a particularly good control of the dynamic improvement, which as a result can be carried out on the system according to the invention. For example, volume and area resources in a settlement or an agglomeration are successively better utilized through repeated use of the invention. System homogeneity is maintained—and in the case of building regulations, these can be automatically taken into account and thus complied with.

According to a further development, building-related secondary data of the selected subsystem is predicted by the artificial neural network.

It has been shown that the artificial neural network is suitable for making suitable suggestions that exploit the potential—in real cases—significantly better than other methods. The artificial neural network can “think” in enormously high-dimensional feature spaces and thus find and take into account correlations in these spaces, which can hardly be captured by manual or otherwise automated access and therefore remain unconsidered. Comparative studies and studies were carried out on real samples such as buildings that have already been built, especially recently built buildings. In the case of these buildings, for example, enormous investments were made and a large number of professionals/experts were employed for a long time to ensure that a solution was found that met the external requirements and demands and at the same time identified the potential that currently exists and exploited it as fully as possible. The artificial neural network was able to reproduce many of the results. In some cases, the results of the professionals could be greatly surpassed by the invention with its artificial neural network. It can therefore be stated that both manual system optimization and other computer-automated system improvements are outperformed by AI in important cases.

According to a further development, the method further comprises a step of measuring at least one point datum by means of LIDAR, in particular by means of an airborne measuring device.

The data can therefore also be measured and recorded as part of the invention itself. This has the advantage that acquisition parameters—for example resolutions or repetition rates—can be adapted to the intended purpose. Self-measured data can also be combined with existing data, for example to increase accuracy. The freshly measured data is also more up-to-date and therefore more accurately represents the actual nature of the physical system compared to, for example, official data, which may be several years old.

According to a further development, the method further comprises a step of identifying improvement potentials by comparing parameters of the selected subsystem in existing form with parameters of the selected subsystem in the form proposed by the artificial neural network, in particular by comparing dimensions of the structural use.

In this way, potentials can be clearly recorded and even “searched for”. The comparison of actual and target values allows a meaningful quantification of the potential behind the optimization of subsystems. The invention can therefore also be used or regarded as an invention of control engineering.

According to a further development, the method further comprises a step of graphically displaying a map, which graphically indicates improvement potentials for two or more subsystems in a way that is (visually) perceptible to the user.

Such a presentation is very helpful and clear for the user. The effect that a graphical representation of the potential for improvement on a type of map or a system overview leads to the perception, processing and reaction of users to the results has been confirmed by a wide range of our users from various user groups.

A wide variety of specific types of graphical representations of the subsystems and the associated improvement potentials are conceivable. The invention is not intended to be limited to one specific type of graphical representation. It is irrelevant whether bar charts, pie charts or other types of representation are used. For example, a user can also choose between various possible types of graphical representation to find one that suits his personal taste or is particularly intuitive and easy to understand.

According to a further development, the method further comprises a step of adapting the physical system by modifying the selected subsystem in the form proposed by the artificial neural network, in particular by building, rebuilding or reconstructing one or more building structures in the selected subsystem.

As a result, the system is successively improved and, in compliance with requirements, sustainably managed in its further development. Recognizing potential and implementing it gives our users enormous competitive advantages and ultimately financial benefits compared to parties who do not have the technical analysis and information to improve the system.

According to a further development, the method further comprises a step of clustering subsystems into related clusters and correspondingly marking the subsystems with respect to their cluster affiliation, in particular using an AI technique of unsupervised learning.

Within subsystem clusters, the latter must be given particular consideration in systems with homogeneity requirements. Clusters may, for example, differ from one another, while the application of a homogeneity rule within the cluster can be more pronounced without jeopardizing the correct function and order of the system. Frequently, certain clusters of buildings, e.g. groups of buildings, are subject to the same or similar building code requirements, and it is necessary or desirable for an individual building to fit into the associated cluster, but not other clusters. This can be particularly relevant at cluster boundaries. For example, a residential area can also border on a commercial area. For houses in this border area, the immediate neighbors are not necessarily relevant if they belong to a different cluster. Cluster affiliation is therefore particularly important here. The same applies, for example, to components or parts of components in micro- or nanoelectronics.

According to a further development, the subsystem data comprises one or more of the following: Firsthohe, Traufhöhe, Höhe eines Daches, Dachwinkel, Grundflächenzahl GRZ, Grundflachenzahl GRZ1, Grundflächenzahl GRZ2, Geschossflächenzahl GFZ, Geschossfläche, Volumen, Anzahl nutzbarer Geschosse, Anzahl der Vollgeschosse, Vorhandensein und AusmaB versiegelter Flschen, Bodenreferenzpunkt, Region, Stadt und/oder Kreis, in dem/der sich das Teilsystem befindet, Maß der baulichen Nutzung eines nächsten Nachbarn, Maß der baulichen Nutzung eines m-nächsten (zweitnächsten, drittnächsten, etc. A Boolean statement as to whether the nearest neighbor is located on the same connection, in particular the same street, as the selected subsystem, a Boolean statement as to whether the m-nearest neighbor is located on the same connection, in particular the same street, as the selected subsystem, a Boolean statement as to whether the nearest neighbor has an open or closed construction, a Boolean statement as to whether the m-nearest neighbor has an open or closed construction, a Boolean statement as to whether the nearest neighbor has a building in the courtyard or on the street, a Boolean statement as to whether the m-nearest neighbor has a building in the courtyard or on the street, a length specification that determines the distance of the building of the nearest neighbor to the street, a length and/or depth specification that determines how deep a house is built into the property in relation to the street, relevant building area, relevant development plans, land use plan, usage regulations according to legal requirements, in particular building use regulations, cluster affiliation of the subsystem to a cluster of subsystems.

These are merely examples, but ones that have proven to be particularly relevant for the application of the present invention to buildings. In this way, a particularly precise prediction of the properties of buildings to be erected is achieved.

m denotes a natural number. It is otherwise freely selectable. This means that all neighbors, for m of any size in principle, can be taken into account (in combinations of all their properties or parts thereof) or not.

For example, individual subsets of the following properties can be taken into account for a finite number of neighbors: Ridge height, eaves height, height of a roof, roof angle, floor area ratio GRZ, floor area ratio GRZ1, floor area ratio GRZ2, floor area ratio GFZ, floor area, volume, number of usable floors, number of full floors, presence and extent of sealed surfaces, soil reference point, region, city and/or district, and much more.

A measure of building use can be, for example: GRZ or GFZ.

Statements concerning relation data (which comprise at least one property that describes a relation between the selected subsystem and other subsystems, in particular non-selected subsystems) can also be taken into account for a finite number of neighbors or not. In practice, the relations can be of any complexity. The only example of such a relation is the simple example in which the statement describes the relation as to whether the selected subsystem and a certain m-nearest neighbor are “on the same street” (yes or no).

It should be emphasized once again that arbitrarily complex derivative variables are possible here on the basis of the relationship between the selected and non-selected subsystem.

The relations can also refer to property-related (i.e. secondary data-related) properties of the subsystems.

According to a further development, the step of using the machine learning model, in particular the artificial neural network, is also based on relation data comprising at least one property that describes a relation between the selected subsystem and other subsystems, in particular non-selected subsystems.

The inclusion of relational data makes the calculation even more precise, as homogeneity requirements can once again be better taken into account. For example, it can be taken into account whether a selected subsystem and another subsystem are located on the same street or belong to the same housing estate. In this context, please refer to the detailed descriptions above

According to a further development, the method further comprises a step of generating LoD data on the basis of the n-dimensional point data, in particular LIDAR data, wherein the step of determining subsystem data is carried out on the basis of the generated LoD data.

This allows LoD data (Level of Detail) to be generated efficiently. This reduces the complexity of the data and simplifies further data processing. The different levels of detail allow easy access to macroscopic variables at low levels of detail, while details are ensured by the higher levels of detail.

The CityGML format is used in one example. This can be used flexibly and increases compatibility and interoperability between program modules as well as with regard to external interfaces.

By using the invention, living space (as well as areas or volumes used for other purposes) can be efficiently redensified. In this way, new sealing of areas can also be avoided, since the use of the present invention allows existing areas to be redensified and/or rededicated before new sealing (e.g. by authorities) is considered.

As redensification usually takes place on already sealed or constructed buildings, the technology counteracts new sealing and thus makes an important contribution to ecological urban development. The invention also helps to reduce climate-damaging CO2 emissions. The climate can thus be positively influenced in the long term, especially if enough stakeholders make use of the present invention.

Furthermore, lightweight construction materials such as solid wood constructions can be used for all types of extensions in order to generate more living space in less space. The invention thus ensures a responsible form of redensification.

The invention also provides computers, computer programs, computer networks, data and computer-readable data carriers as well as a method for training an artificial neural network according to the invention.

All features disclosed in connection with corresponding methods can be used in connection with the devices and computer programs, and vice versa.

Although some aspects have been described in the context of a device, it is clear that these aspects also constitute a description of the corresponding method, wherein a block or device corresponds to a method step or a function of a method step. Similarly, aspects described in the context of a method step also constitute a description of a corresponding block or element or feature of a corresponding device.

Embodiments of the invention can be realized in a computer system. The computing system may be a local computing device (e.g., personal computer, laptop computer, tablet computer, or cell phone) having one or more processors and one or more storage devices, or may be a distributed computing system (e.g., a cloud computing system having one or more processors or one or more storage devices distributed at various locations, for example, at a local client and/or one or more remote server farms and/or data centers). The computer system may comprise any circuitry or combination of circuitry. In one embodiment, the computer system may comprise one or more processors, which may be of any type. As used herein, processor may mean any type of computing circuit, such as, but not limited to, a microprocessor, a microcontroller, a complex instruction set microprocessor (CISC), a reduced instruction set microprocessor (RISC), a very long instruction word (VLIW) microprocessor, a VLIW microprocessor, a VLIW microprocessor, and a VLIW microprocessor; VLIW) microprocessor, a graphics processor, a digital signal processor (DSP), a multi-core processor, a field-programmable gate array (FPGA), or any other type of processor or processing circuit. Other types of circuitry that may be included in the computer system may be a custom-built circuit, an application-specific integrated circuit (ASIC), or the like, such as one or more circuits (e.g., a communication circuit) for use in wireless devices such as cellular phones, tablet computers, laptop computers, two-way radios, and similar electronic systems. The computer system may include one or more storage devices, which may include one or more storage elements suitable for the particular application, such as a main memory in the form of random access memory (RAM), one or more hard disks, and/or one or more drives that handle removable media, such as CDs, flash memory cards, DVDs, and the like. The computer system may also include a display device, one or more speakers, and a keyboard and/or controller, which may include a mouse, trackball, touch screen, voice recognition device, or any other device that allows a system user to input information to and receive information from the computer system.

Some or all of the method steps may be performed by (or using) a hardware device, such as a processor, a microprocessor, a programmable computer or an electronic circuit. In some embodiments, one or more of the main method steps may be performed by such a device.

Depending on specific implementation requirements, embodiments of the invention may be implemented in hardware or software. The implementation may be performed using a non-volatile storage medium such as a digital storage medium, such as a floppy disk, a DVD, a Blu-Ray, a CD, a ROM, a PROM and EPROM, an EEPROM or a FLASH memory, on which electronically readable control signals are stored that interact (or are capable of interacting) with a programmable computer system such that the particular method is performed. Therefore, the digital storage medium may be computer readable.

Some embodiments according to the invention comprise a data carrier with electronically readable control signals that can interact with a programmable computer system so that one of the methods described herein is performed.

In general, embodiments of the present invention may be implemented as a computer program product comprising a program code, wherein the program code is effective for executing one of the methods when the computer program product is running on a computer. For example, the program code may be stored on a machine-readable medium.

Further embodiments comprise the computer program for performing one of the methods described herein, which is stored on a machine-readable medium.

In other words, an embodiment of the present invention is therefore a computer program comprising a program code for performing any of the methods described herein when the computer program is running on a computer.

Thus, another embodiment of the present invention is a storage medium (or data carrier or computer readable medium) comprising a computer program stored thereon for executing one of the methods described herein when executed by a processor. The data carrier, digital storage medium or recorded medium is generally tangible and/or non-transitory. Another embodiment of the present invention is an apparatus as described herein comprising a processor and the storage medium.

Thus, another embodiment of the invention is a data stream or signal sequence representing the computer program for performing one of the methods described herein. The data stream or signal sequence may, for example, be configured to be transmitted over a data communication link, for example over the Internet.

Another embodiment comprises a processing means, for example a computer or programmable logic device, configured or adapted to perform any of the methods described herein.

Another embodiment comprises a computer on which the computer program for executing one of the methods described herein is installed.

Another embodiment according to the invention comprises a device or system configured to transmit (for example, electronically or optically) a computer program for performing any of the methods described herein to a receiver. The receiver may be, for example, a computer, a mobile device, a storage device, or the like. The device or system may include, for example, a file server for transmitting the computer program to the receiver.

In some embodiments, a programmable logic device (e.g., a field programmable gate array, FPGA) may be used to perform some or all of the functionalities of the methods described herein. In some embodiments, a field programmable gate array may cooperate with a microprocessor to perform any of the methods described herein. In general, the methods are preferably performed by any hardware device.

Embodiments may be based on using a machine learning model/machine learning model or machine learning algorithm. Machine learning may refer to algorithms and statistical models that computer systems can use to perform a particular task without using explicit instructions, rather than relying on models and inference. For example, machine learning may use a transformation of data that can be derived from an analysis of historical and/or training data, rather than a transformation of data based on rules. For example, the content of images can be analyzed using a machine learning model or using a machine learning algorithm. In order for the machine learning model to analyze the content of an image, the machine learning model can be trained using training images as input and training content information as output. By training the machine learning model with a large number of training images and/or training sequences (e.g. words or sentences) and associated training content information (e.g. labels or annotations), the machine learning model “learns” to recognize the content of the images so that the content of images not included in the training data can be recognized using the machine learning model. The same principle can also be used for other types of sensor data: By training a machine learning model using training sensor data and a desired output, the machine learning model “learns” a transformation between the sensor data and the output, which can be used to provide an output based on non-training sensor data provided to the machine learning model. The provided data (e.g. sensor data, metadata and/or image data) can be pre-processed to obtain a feature vector, which is used as input to the machine learning model.

Machine learning models can be trained using training input data. The above examples use a training method called supervised learning. In supervised learning, the machine learning model is trained using a plurality of training samples, where each sample may include a plurality of input data values and a plurality of desired output values, i.e. each training sample has a desired output value associated with it. By specifying both training samples and desired output values, the machine learning model “learns” which output value to provide based on an input sample that is similar to the samples provided during training. In addition to supervised learning, semi-supervised learning can also be used. In semi-supervised learning, some of the training samples lack a desired output value. Supervised learning can be based on a supervised learning algorithm (e.g. a classification algorithm, a regression algorithm or a similarity learning algorithm). Classification algorithms can be used when the outputs are restricted to a limited set of values (categorical variables), i.e. the input is classified as one of the limited set of values. Regression algorithms can be used when the outputs are any numerical value (within a range). Similarity learning algorithms can be similar to both classification and regression algorithms, but are based on learning from examples using a similarity function that measures how similar or related two objects are. In addition to supervised learning or semi-supervised learning, unsupervised learning can be used to train the machine learning model. In unsupervised learning, (only) input data may be provided and an unsupervised learning algorithm can be used to find a structure in the input data (e.g. by grouping or clustering the input data, finding similarities in the data). Clustering is the assignment of input data comprising a plurality of input values into subsets (clusters) so that input values within the same cluster are similar according to one or more (predefined) similarity criteria, while they are dissimilar to input values comprised in other clusters.

Reinforcement learning is a third group of machine learning algorithms. In other words, reinforcement learning can be used to train the machine learning model. In reinforcement learning, one or more software agents are trained to perform actions in an environment. A reward is calculated based on the actions performed. Reinforcement learning is based on training the one or more software agents to select the actions such that the cumulative reward is increased, resulting in software agents that become better at the task they are given (as evidenced by increasing rewards).

Furthermore, some techniques can be applied to some of the machine learning algorithms. For example, feature learning may be used. In other words, the machine learning model may be trained using feature learning, at least in part, and/or the machine learning algorithm may comprise a feature learning component. Feature learning algorithms, called representation learning algorithms, may receive the information in their input but transform it so that it becomes useful, often as a pre-processing stage before performing classification or prediction. Feature learning can, for example, be based on principal component analysis or cluster analysis.

In some examples, anomaly detection (i.e., outlier detection) may be used, which aims to provide identification of input values that raise suspicion as being significantly different from the majority of input and training data. In other words, the machine learning model may be trained at least in part using anomaly detection, and/or the machine learning algorithm may comprise an anomaly detection component.

In some examples, the machine learning algorithm can use a decision tree as a prediction model. In other words, the machine learning model can be based on a decision tree. In a decision tree, the observations on an item (e.g., a set of input values) may be represented by the branches of the decision tree, and an output value corresponding to the item may be represented by the leaves of the decision tree. Decision trees can support both discrete values and continuous values as output values. When discrete values are used, the decision tree can be called a classification tree; when continuous values are used, the decision tree can be called a regression tree.

Association rules are another technique that can be used in machine learning algorithms. In other words, the machine learning model can be based on one or more association rules. Association rules are created by identifying relationships between variables in large amounts of data. The machine learning algorithm may identify and/or utilize one or more relationship rules that represent knowledge derived from the data. The rules can be used, for example, to store, manipulate or apply the knowledge.

Machine learning algorithms are usually based on a machine learning model. In other words, the term “machine learning algorithm” may denote a set of instructions that can be used to create, train or use a machine learning model. The term “machine learning model” may denote a data structure and/or a set of rules representing the learned knowledge (e.g., based on the training performed by the machine learning algorithm). In embodiments, the use of a machine learning algorithm may imply the use of an underlying machine learning model (or a plurality of underlying machine learning models). The use of a machine learning model may imply that the machine learning model and/or the data structure/set of rules that is/are the machine learning model is/are trained by a machine learning algorithm.

For example, the machine learning model can be an artificial neural network (ANN). ANNs are systems inspired by biological neural networks, such as those found in a retina or brain. ANNs comprise a number of interconnected nodes and a number of connections, called edges, between the nodes. There are usually three types of nodes, input nodes that receive input values, hidden nodes that are (only) connected to other nodes, and output nodes that provide output values. Each node can represent an artificial neuron. Each edge can send information, from one node to another. The output of a node can be defined as a (non-linear) function of the inputs (e.g. the sum of its inputs). The inputs of a node can be used in the function based on a “weight” of the edge or node providing the input. The weight of nodes and/or edges can be adjusted in the learning process. In other words, training an artificial neural network may comprise adjusting the weights of the nodes and/or edges of the artificial neural network, i.e. to achieve a desired output for a particular input.

Alternatively, the machine learning model can be a support vector machine, a random forest model or a gradient boosting model. Support vector machines (i.e. support vector networks) are supervised learning models with associated learning algorithms that can be used to analyze data (e.g. in a classification or regression analysis). Support Vector Machines can be trained by providing an input with a plurality of training input values belonging to one of two categories. The Support Vector Machine can be trained to assign a new input value to one of the two categories. Alternatively, the machine learning model may be a Bayesian network, which is a probabilistic directed acyclic graphical model. A Bayesian network may represent a set of random variables and their conditional dependencies using a directed acyclic graph. Alternatively, the machine learning model can be based on a genetic algorithm, which is a search algorithm and heuristic technique that mimics the process of natural selection.

### FIGURE LIST

The present invention is explained in more detail below with reference to the embodiments shown in the schematic figures in the drawings. They show:

FIG. 1 is a schematic representation of a LIDAR survey using an airplane,

FIG. 2 is a schematic representation of an embodiment of the present invention,

FIG. 3a-d an example of a plot of land with a house based on ALKIS and LIDAR data,

FIG. 4a-d a second exemplary plot with house based on ALKIS and LIDAR data,

FIG. 5 a schematic representation of a small settlement for the purpose of illustrating the present invention,

FIG. 6 is a schematic overview of a data flow according to an embodiment of the present invention,

FIG. 7 is a schematic representation of a deep neural network for use as a machine learning model in the context of the present invention,

FIG. 8 a schematic representation of a data connection and flow according to an embodiment of the present invention.

In all figures, identical or functionally identical elements and devices have been given the same reference symbols, unless otherwise stated.

### DESCRIPTION OF THE DRAWINGS

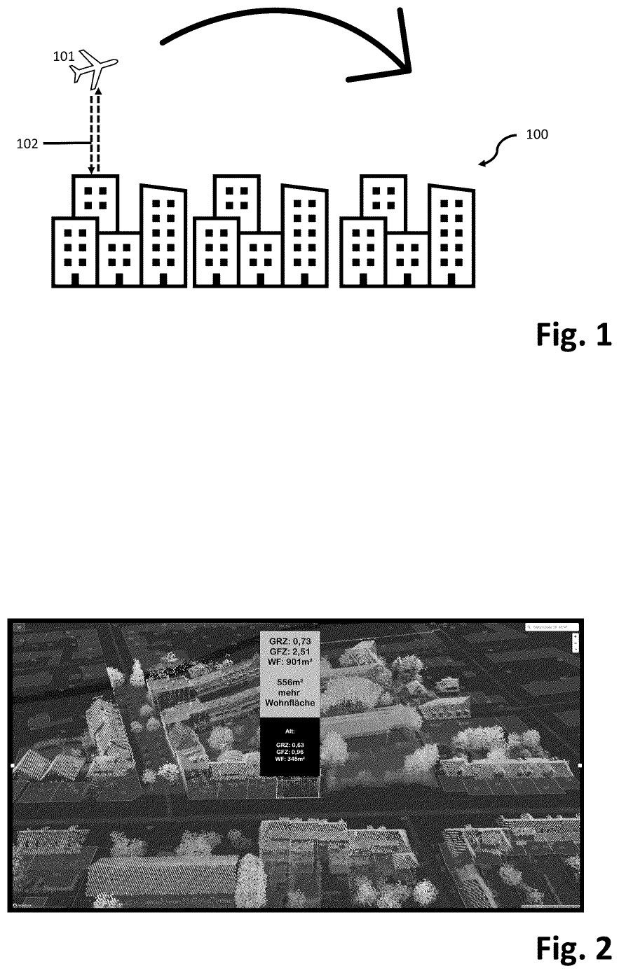

FIG. 1 shows a schematic representation of a LIDAR survey of a physical system 100, symbolized here by various buildings 100, which are arranged on a surface of the earth. The aircraft 101 is flying and carrying a LIDAR surveying device. During the flight of the aircraft 101, the LIDAR surveying device emits signals 102 which are reflected by the buildings 100 or by the surface of the physical system 100 facing the aircraft.

The signals can generally be emitted and received in all directions. The signal 102 is only shown in the figure as perpendicular to the earth's surface by way of example and schematically.

Using appropriate reconstruction algorithms, a raster-resolved map (“LIDAR point clouds”) can be created, which attempts to reproduce the surface of the physical system.

An arrow indicates that the aircraft is moving during the flight. The resulting “LIDAR map” is gradually expanded.

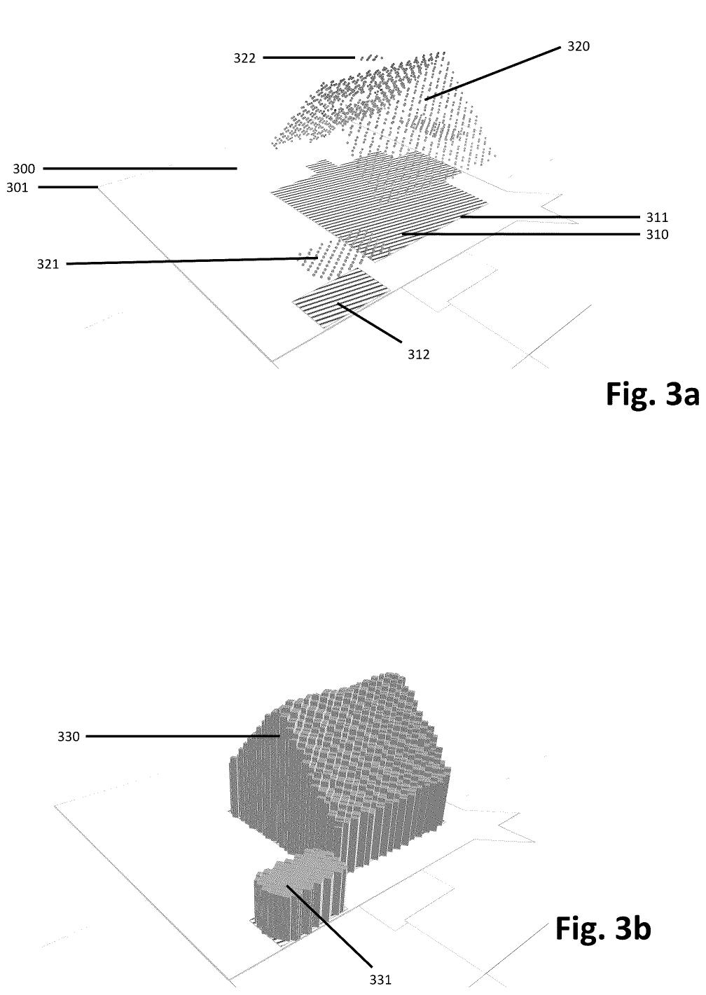

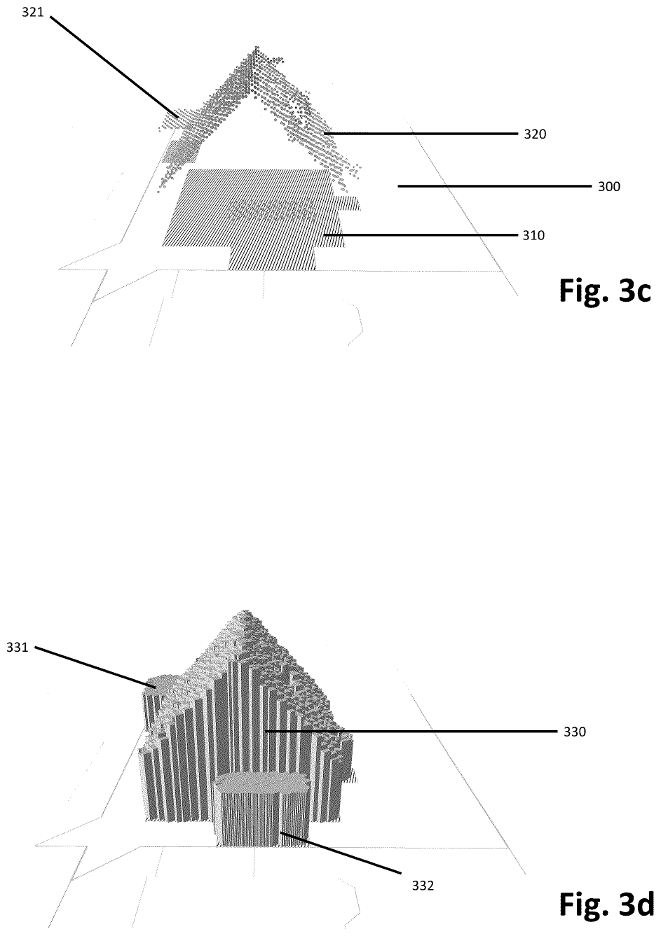

FIGS. 3a and b show a house on a plot of land. FIGS. 3c and d show this from a different angular perspective.

The plot 100 is defined by a border 301. A hatched area 310 shows the part of the plot on which a house is located. The house has an edge 311 on the plot. There is also an area 312 in which an ancillary facility is located. This data on the plot of land and the building facilities is derived, for example, from data from an official real estate cadastre information system (ALKIS).

LIDAR point data 320, 321, 322 are also shown. Data 320 shows a roof of the house, data 322 a chimney located on top of it. Data 321 shows the relatively flat roof of the outdoor facility (e.g. garage).

The LIDAR data is intersection point data in the sense of the invention and its further embodiments. In this embodiment, raw LIDAR data in the area of the property 300 has been “intersected” with the developed parts of the property 310, 312. Thus, shows the LIDAR points that are located above the developed parts of the property 310, 312. In other words, the points of the roof 320, for example, lie within the edge 311 of the house when projected into the plane of the property 300.

FIG. 3b graphically illustrates a numerical integration of the house and the outdoor facilities. As already described in detail, this method can be used to calculate the usable volume and a floor space, for example. The column model shown here can also be used as a basis for other determinations, such as determining the number of usable storeys. In FIG. 3d, the extension 332 is also clearly visible.

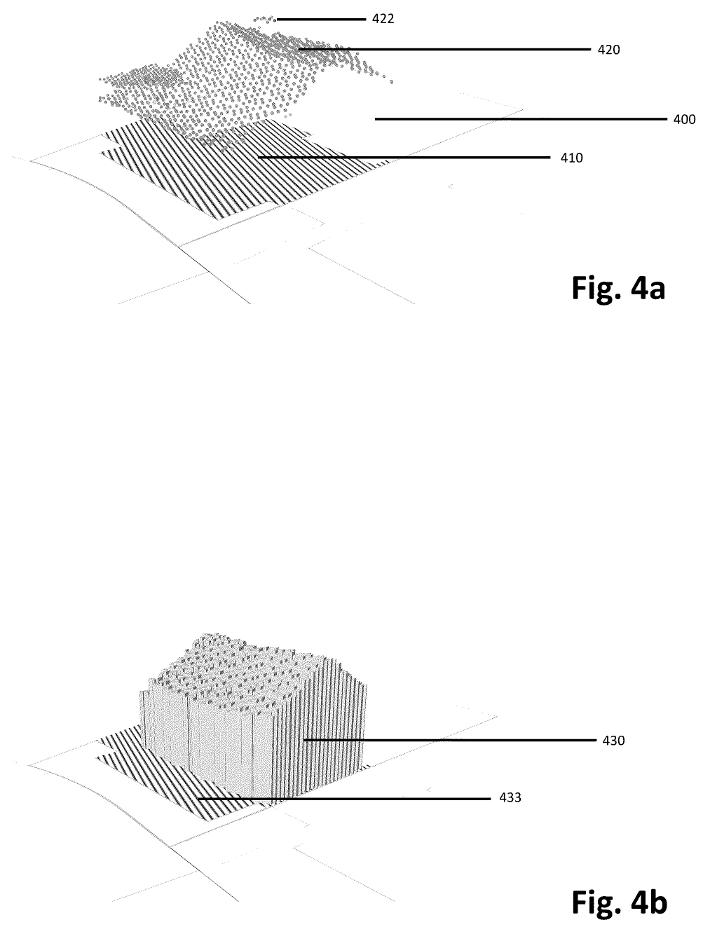

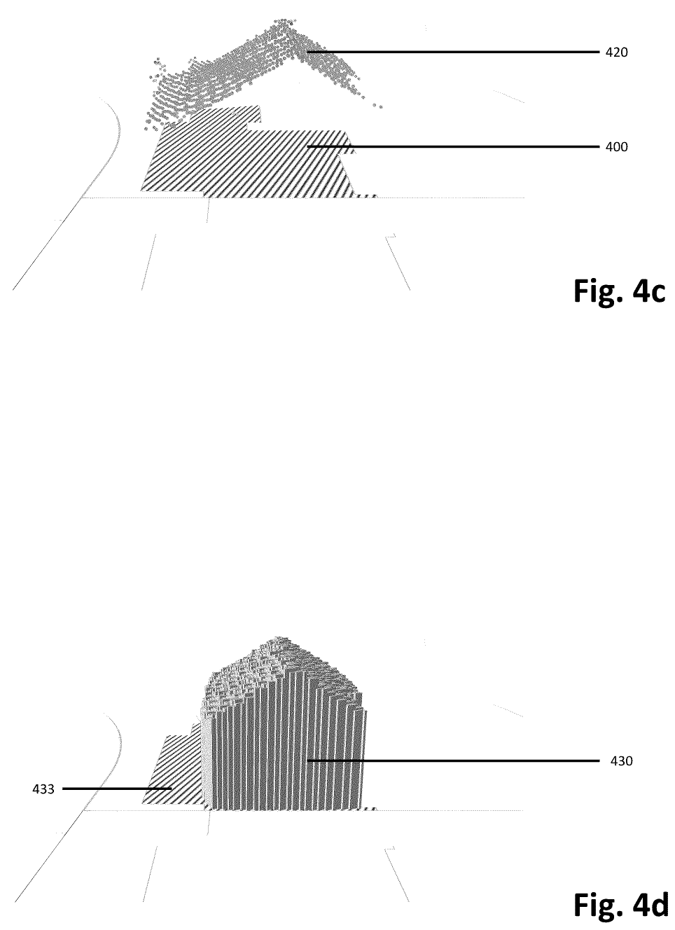

FIGS. 4a-d show a second exemplary plot of land with a house based on ALKIS and LIDAR data. In this case, an ancillary facility 433 is attached directly to the house. This circumstance is not recognizable from the roof 420 alone. However, by correctly evaluating secondary data (here: ALKIS data), the volume of the (main) house 430 is correctly integrated numerically (see in particular FIGS. 4b and 4d). Other relevant quantities are also correctly determined within the scope of the invention. The invention can therefore also process such a case correctly and is not “misled” by the roof, i.e. is not led to incorrect conclusions.

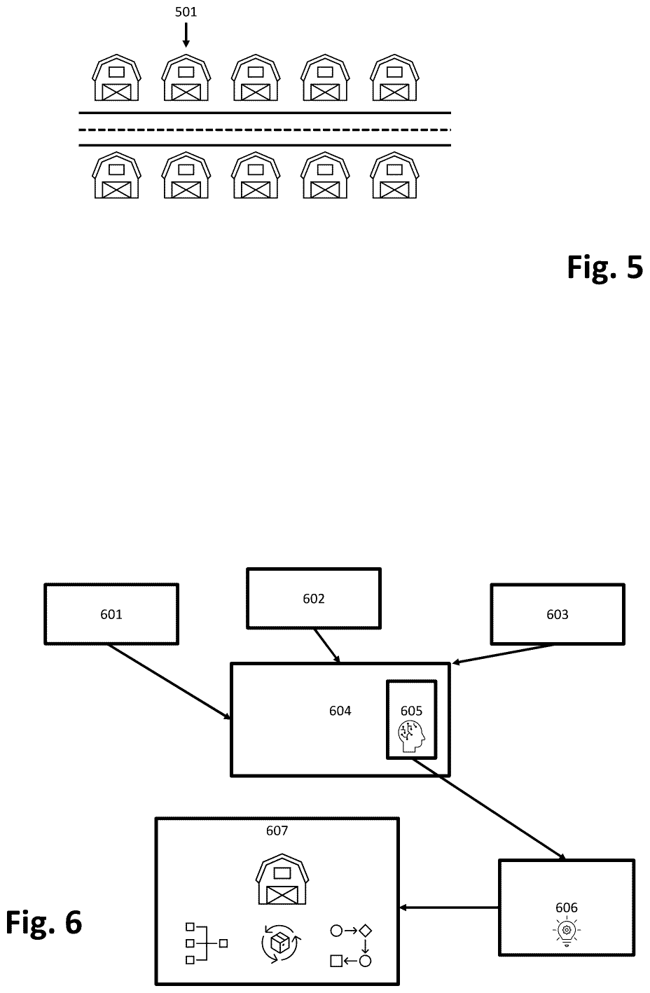

FIG. 5 shows a schematic representation of a small settlement for the purpose of illustrating the present invention. Schematically, five houses are located on opposite sides of a street. For example, the houses are each arranged on a separate plot of land, with each plot comprising a parcel of land.

The houses with land represent subsystems. A subsystem 501 is selected. The invention is now able to recognize and implement potential improvements in the settlement shown.

In a simple—schematic—example with the selected subsystem 501, a prediction is now made on the basis of the surrounding houses as to how the plot of land of subsystem 501 could be built on or better used. This is done on the basis of the properties of the plot (secondary data of the selected subsystem) and on the basis of the surrounding nine plots and their houses (subsystem data of the non-selected subsystems). Relational data describing the relationship between the subsystem 501 and the surrounding nine houses and properties can also be taken into account, for example. In a simple example, it is taken into account that the 10 houses are all located on the same street. In another example, it is taken into account that four houses are on the same side of the street and/or that five houses are on the other side of the street. An evaluation of “how” relevant the properties of the four houses are, for example in comparison to the properties of the five houses, is performed by the present invention, in particular by using machine learning (based on training of the machine learning model).

In one example, the already existing house of subsystem 501 is not taken into account. It is considered as a variable in the context of the system improvement. As a result, however, such a house could be modified, extended or rebuilt.

FIG. 6 shows a schematic overview of a data flow according to an embodiment of the present invention. LIDAR or 3D model data/LoD data 601, ALKIS data 602 and photogrammetry data 603 flow into an analysis 604 with machine learning model 605. By combining these data sources, the inventions can profitably utilize and evaluate synergies between the data sets. A proposal or prediction 606 is output for one or more selected subsystems, which is then implemented in reality. For example, a building is constructed, extended or adapted, or a process is adapted, or a circuit (element) or a qubit is modified.

The data flow shown can be regarded as a regulation and/or control circuit for the physical system.

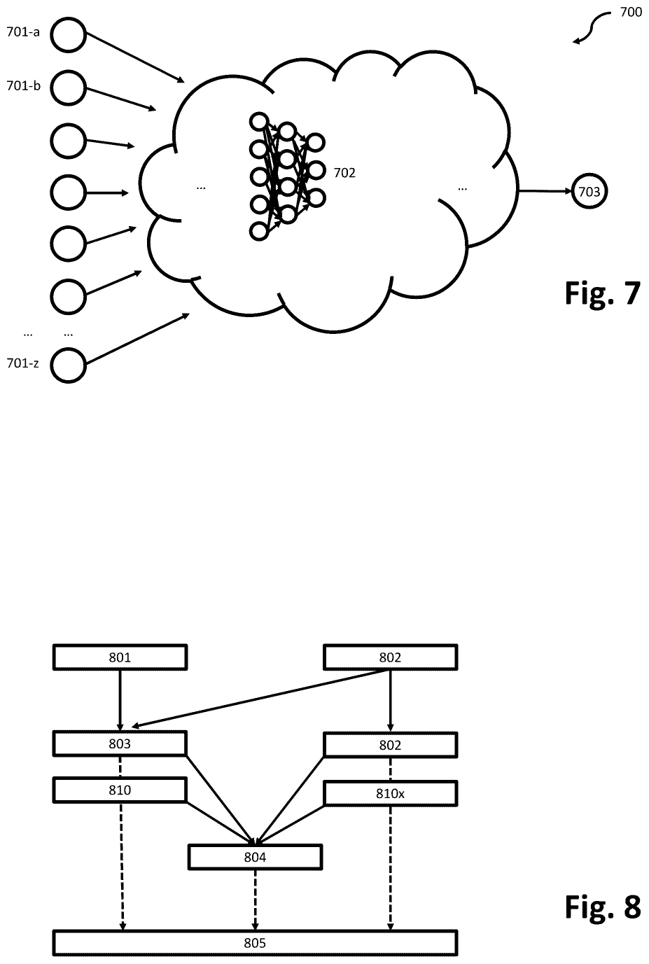

FIG. 7 shows a schematic representation of a deep neural network for use as a machine learning model in the context of the present invention. The deep neural network (artificial neural network) has at least one input neuron 701, usually several, in particular numerous (the designation 701a-z is merely symbolic and in no way limits the number). There is at least one output neuron 703, between which various structures may be arranged, in particular one or more hidden layers 702.

For example, secondary data of a selected subsystem and subsystem data of non-selected subsystems, but also, for example, relation data between selected and non-selected subsystems can be input at the input neurons 701a-z.

At the output neuron 703, for example, a prediction is made available as to how a selected subsystem could be modified or rebuilt.

FIG. 8 shows a schematic representation of a data connection and flow according to one embodiment of the present invention. Reference is made to the general part of the discussion of the invention.

The subsystem data 803 can comprise and/or be derived from the secondary data and the LIDAR/LoD data 801. A prediction 805 is made possible by a machine learning model. The secondary data 802 is taken into account for the selected subsystem 810x. The subsystem data 803 is taken into account in particular for non-selected subsystems 810. In addition, relation data 804 can be created or derived and successively taken into account.

### LIST OF REFERENCE SYMBOLS

100 Physical system
101 Airplane
102 Measuring signal
300 Property (here identical with parcel)
301 Edge of the property (edge of the parcel)
310 Developed part of land (house)
311 Edge of the developed part of the property (i.e. the house)
312 Developed part of land (outdoor area)
320 Roof of a house/“point cloud” of the intersection point data
321 Roof of an auxiliary system/“point cloud” of the intersection point data
322 Schonstein/Chimney
330 Numerically integrated house/volume
331 Numerically integrated auxiliary system/volume
332 Numerically integrated attachment/volume
400 Property (here identical with parcel)
410 Developed part of land (house)
420 Roof of a house/“point cloud” of the intersection point data (shown here including ancillary system)
422 Schonstein/Chimney
430 Numerically integrated house/volume (in this case without an annex directly adjacent to the house)
433 Developed part of the property (here, however, belonging to the ancillary facility)
501 Selected subsystem/selected plot or building
601 LIDAR/LoD data
602 ALKIS data
603 Photogrammetry data
604 Analysis
605 Machine learning model, in particular artificial neural network
606 Proposal/prediction
607 Implementation (construction of a building, adaptation of a process, Adaptation of a circuit, modification of a qubit, etc.)
700 Artificial neural network (schematic)
701-(a-z) exemplary input neurons
702 Exemplary hidden layers (schematic)
703 Exemplary output neuron
801 LIDAR/LoD data
802 Secondary data
803 Subsystem data
804 Relational data
805 Forecast/potential/result
810 Non-selected subsystems
810x Selected subsystem(s) (x indicates selected)

1-24. (canceled)

25. A method for optimizing volume and/or area utilizations in a physical system, comprising:
identifying (S01) a physical system in an n-dimensional space, in particular a three-dimensional space;
identifying (S02) an (n−1)-dimensional space, in particular a two-dimensional space, which is suitable for describing an (n−1)-dimensional projection of the physical system in n-dimensional space;
provisioning (S03) of n-dimensional point data, in particular LIDAR data, and/or LoD data, which describe in particular one or more surfaces;
provisioning (S04) of secondary data comprising (n−1)-dimensional data, in particular polygon data, in particular of a cadastre, which in particular describe one or more levels;
identifying (S05) one or more subsystems in the physical system, in particular by means of the secondary data, in particular also by assigning secondary data to the subsystems;
determining (S06) subsystem data of at least two subsystems, which describe variables of the respective subsystem, in particular comprising the secondary data of the respective subsystem and the n-dimensional point data and/or LoD data for the respective subsystem, in whole or in part;
selecting (S07) at least one subsystem; and
using (S08) a machine learning model of supervised learning, in particular an artificial neural network and/or linear regression, for predicting properties of the selected subsystem on the basis of the secondary data of the selected subsystem and of subsystem data from other, unselected subsystems.

26. The method according to claim 25, wherein the machine learning model, in particular the artificial neural network, is and/or has been trained using a selected subset of existing subsystems, in particular by means of supervised learning of the artificial neural network.

27. The method according to claim 26, wherein subsystems are selected which have a high utilization, in particular volume and area utilization, in the secondary and/or subsystem data, in particular characterized by exceeding and/or falling below threshold values in relation to the secondary and/or subsystem data.

28. The method according to claim 25, further comprising:
providing photogrammetry data relating to the n- and/or (n−1)-dimensional space; and
deriving at least one quantity from the photogrammetry data, in particular in combination with the secondary data and/or subsystem data.

29. The method according to claim 28, further comprising:
recognizing at least one sealed area and its dimensions based on the photogrammetry data.

30. The method according to claim 28, further comprising:
determining a ground reference point by recognizing an object in the photogrammetry data that is suitable for use as a ground reference point, in particular manhole and manhole covers;
intersecting the dimensions of the recognized object with the n-dimensional point data to generate intersection point data; and
forming an average of the intersection point data to determine the ground reference point.

31. The method according to claim 25, further comprising:
intersecting n-dimensional point data with a building part of a subsystem defined by the secondary data to generate intersection point data; and
marking the points of the intersection point data which fall within the range of the building part in the n-dimensional point data.

32. The method according to claim 31, wherein a classification and marking of points as roof points takes place on the set of intersection point data, in particular a clustering and/or by unsupervised learning, in particular on the basis of the Euclidean distance of the points from one another as a relevant measure and/or on the basis of the vertical distance, in particular the vertical or z-component, of the points from one another as a relevant measure, and/or on the basis of normal vectors.

33. The method according to claim 25, further comprising:
classifying and labeling points as roof points based on a trained second machine learning model, in particular a second artificial neural network.

34. The method according to claim 33, wherein the second machine learning model is and/or has been trained by a method comprising intersecting n-dimensional point data with a building part of a subsystem defined by secondary data to generate intersection point data.

35. The method according to claim 34, wherein a classification and marking of points as roof points takes place on the set of intersection point data, in particular a clustering and/or by unsupervised learning, in particular on the basis of the Euclidean distance of the points from one another as a relevant measure and/or on the basis of the vertical distance, in particular the vertical or z-component, of the points from one another as a relevant measure, and/or on the basis of normal vectors.

36. The method according to claim 25, wherein an incoming feature vector of the machine learning model, in particular of the artificial neural network, comprises, on the one hand, secondary data of the selected subsystem, in particular property-related secondary data, and, on the other hand, subsystem data of other, non-selected subsystems, in particular relation data which comprise at least one property which describes a relation between the selected subsystem and other subsystems, in particular non-selected subsystems.

37. The method according to claim 25, wherein secondary data, in particular building-related secondary data, of the selected subsystem are predicted by the machine learning model, in particular the artificial neural network.

38. The method according to claim 25, further comprising:
measuring at least one point datum by means of LIDAR, in particular by an airborne measuring device.

39. The method according to claim 25, further comprising:
identifying improvement potentials by comparing parameters of the selected subsystem in existing form with parameters of the selected subsystem in the form proposed by the machine learning model, in particular by the artificial neural network, in particular by comparing measures of structural use.

40. The method according to claim 39, further comprising:
graphically displaying a map which graphically indicates improvement potentials for two or more subsystems perceptibly for the user.

41. The method according to claim 25, further comprising:
adapting the physical system by modifying the selected subsystem, in the form proposed by the machine learning model, in particular the artificial neural network, in particular by building, rebuilding or reconstructing one or more building structures in the selected subsystem.

42. The method according to claim 25, further comprising:
clustering subsystems into related clusters and correspondingly labeling the subsystems with respect to their cluster membership, in particular using an AI technique of unsupervised learning.

43. The method according to claim 25, wherein the subsystem data comprises one or more of:
ridge height, eaves height, roof height, roof angle, floor area ratio GRZ, floor area ratio GRZ1, floor area ratio GRZ2, floor area ratio GFZ, floor area, volume, number of usable floors, number of full floors;
existence and extent of sealed surfaces;
ground reference point;
region, city and/or district in which the subsystem is located;
dimension of the building use of a nearest neighbor;
dimension of the building use of a m-nearest (second-nearest, third-nearest, etc.) neighbor;
a Boolean statement as to whether the nearest neighbor is located on the same connection, in particular the same street, as the selected subsystem;
a Boolean statement as to whether the m-nearest neighbor is located on the same connection, in particular the same street, as the selected subsystem;
a Boolean statement as to whether the nearest neighbor has an open or closed construction method;
a Boolean statement as to whether the m-nearest neighbor has an open or closed construction method;
a Boolean statement as to whether the nearest neighbor has a building in the courtyard or on the street;
a Boolean statement as to whether the m-nearest neighbor has a building in the courtyard or on the street;
a length specification that determines the distance of the nearest neighbor's building to the street;
a length and/or depth specification that determines how deep a house is built into the property in relation to the street;
relevant building area;
relevant development plans;
usage regulations in accordance with legal requirements, in particular building use regulations; or
cluster affiliation of the subsystem to a cluster of subsystems.

44. The method according to claim 25, wherein utilizing (S08) the machine learning model, in particular the artificial neural network, is further performed on the basis of:
relation data comprising at least one property describing a relation between the selected subsystem and other subsystems, in particular non-selected subsystems.

45. The method according to claim 25, further comprising:
generating LoD data based on the n-dimensional point data, in particular LIDAR data, wherein determining subsystem data (S06) is performed based on the generated LoD data.

46. One or more non-transitory computer-readable media having instructions stored thereon that, when executed by one or more processors, cause the one or more processors to perform operations comprising the method according to claim 25, and data generated according to said method, or a computer-readable data carrier comprising said data.

47. The one or more non-transitory computer-readable media according to claim 46, where in the operations relate to the optimization of volume and space utilization, in the real estate and/or in the logistics sector and/or for integrated circuits and/or systems comprising two or more qubits.

48. A method of training a supervised machine learning model, in particular an artificial neural network and/or a linear regression, which is suitable to be used for and/or to effect the method according to claim 25.
